(19) United States
(12) Patent Application Publication
(10) Pub. No.: US 2011/0017299 A1
(43) Pub. Date: Jan. 27, 2011

(54) Solar Sheath

(76) Inventor: Joe Thornton McCormack, JR., Phoenix, AZ (US)

Correspondence Address: Joe T. McCormack, PO Box 31926, Mesa, AZ, 85275, US

(21) Appl. No.: 12/462,035

(22) Filed: Jul. 27, 2009

(51) Int. Cl. H01L 31/00

(52) U.S. Cl. 136/261

(57) ABSTRACT

The invention is a n-type silicon front contact conductor comprised entirely of at least one or more tube assemblies that allow the capture of electromagnetic radiation in addition to collecting freed electrons from the n-type silicon from the photovoltaic effect of a photovoltaic cell and also providing a means of cooling the wound wire within the tube assemblies with a gas or liquid.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC

Not Applicable

### BACKGROUND OF THE INVENTION

1. Field of the Invention

The field of invention to which this invention pertains is the n-type silicon front contact conductor that collects freed electrons from the n-type silicon that is directly exposed to photons that interact with it, producing the photovoltaic effect in photovoltaic cells.

2. Background Art

The physical presence of the n-type silicon front contact conductor, while needed to collect electrons freed from the photovoltaic effect, is a physical barrier that limits the interaction of photons with the n-type silicon. The result is lower energy production of the photovoltaic cell.

### BRIEF SUMMARY OF THE INVENTION

This invention is drawn toward the physical space taken up by the n-type silicon front contact conductor in that, while the n-type silicon front contact conductor is needed in order to gather freed electrons from the n-type silicon, the physical space of the n-type silicon front contact conductor prevents a small percentage of photons from interacting with the n-type silicon by reflecting, diffusing or absorbing photons with its physical space that results in loss of energy produced. In order to compensate for the lost energy production from the physical space taken up by the n-type silicon front contact conductor, the n-type silicon front contact conductor is entirely comprised of a series of outer round, hollow and non-electrically conductive tubes containing inner round hollow and non-electrically conductive tubes. The inner tubes serve as round structures that conductive wire is wound around enabling that conductive wire to absorb electromagnetic radiation to create energy. The inner tubes also serve as a material guide, through which a gas or fluid may pass within, in order to absorb thermal energy collected by the wound wire. The outer tubes serve as an electrically isolative casing between the wire winding and the n-type silicon that the outer tubes are in direct physical contact with. The physical area that the outer tubes directly contact the n-type silicon is coated with a conductive material enabling the physical contact area of the outer tubes to collect freed electrons from the n-type silicon.

### BRIEF DESCRIPTION OF THE DRAWINGS

The suggested invention is illustrated by the drawings submitted on FIGS. 1-4.

FIG. 1 is a cross section of the outer tube, the wound wire and a cross section of the inner tube.

FIG. 2 is a side view of the outer tube and conductive material bonded to one half of the outer circumference of the outer tube.

FIG. 3 is a side view of the outer tube, the conductive material bonded to one half of the outer circumference of the outer tube and the n-type silicon that the conductive material is in direct contact with, a depiction of the sun is present to show that the outer tube bonded to the conductive material is bonded to the front surface of the n-type silicon.

FIG. 4 is a front view of the n-type silicon with a series of outer tubes of the same width as the n-type silicon equally distributed across the surface of the n-type silicon.

### DETAILED DESCRIPTION OF THE INVENTION

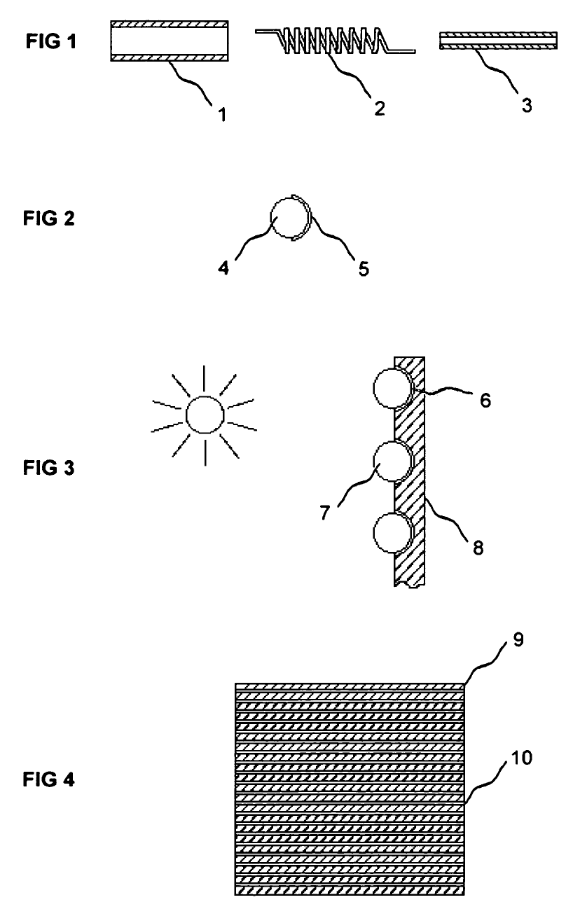

In FIG. 1, the inner tube 3 is wound with conductive wire 2 around its outer circumference, both 3 and 2 are placed within the outer tube 1 and are the same length as the outer tube 1. In FIG. 2, the outer circumference of the outer tube 4 is shown with conductive material 5 bonded to one half of its outer circumference and of the same length as the outer tube, since that conductive material is in direct contact with the n-type silicon as shown by FIG. 3. In FIG. 3, the conductive material 6 is bonded to one half of the outer circumference of the outer tube 7 and is the same length as outer tube 7, the conductive material 6 is in direct contact with the front surface of the n-type silicon 8. In FIG. 4, an evenly distributed collection of outer tubes 10 is in direct contact with the front surface of the n-type silicon 9, the outer tubes 10 are the same length as the n-type silicon 9. It will be understood by those skilled in the art that various changes in form and details may be made therein without departing from the spirit and scope of the invention.

What is claimed is:

1. A n-type silicon front contact conductor entirely comprised of one or more tube assemblies, a tube assembly comprising:
a hollow outer tube which is not electrically conductive with one half of its outer circumference bonded to a conductive material wherein both the outer tube and the conductive material are the same length as the length of the n-type silicon surface, so that the conductive material which is bonded to the outer tube will be bonded to the n-type silicon;
a conductive wound wire, to absorb electromagnetic radiation, that is the same length as the outer tube and placed within the outer tube;
a hollow inner tube which is not electrically conductive that is the same length as the outer tube and placed within the conductive wound wire, the internal diameter of the inner tube of sufficient size to allow the passage of a gas or fluid with the purpose of that gas or fluid to absorb thermal energy from the conductive wound wire.
